(19) United States
(12) Patent Application Publication
(10) Pub. No.: US 2014/0083758 A1
(43) Pub. Date: Mar. 27, 2014

(54) MAGNETIC BOARD AND METHOD FOR MANUFACTURING THE SAME

(71) Applicant: SAMSUNG ELECTRO-MECHANICS CO., LTD., Gyunggi-do (KR)

(72) Inventors: Jung Tae Park, Gyunggi-do (KR); Sung Yong An, Gyunggi-do (KR); Dong Hyeok Choi, Gyunggi-do (KR); Seung Heon Han, Gyunggi-do (KR); Yong II Kwon, Gyunggi-do (KR)

(73) Assignee: SAMSUNG ELECTRO-MECHANICS CO., LTD., Gyunggi-do (KR)

(21) Appl. No.: 13/692,581

(22) Filed: Dec. 3, 2012

(30) Foreign Application Priority Data
Sep. 26, 2012 (KR) 10-2012-0107136

(51) Int. Cl. H05K 9/00

(52) U.S. Cl. CPC H05K 9/0081
USPC 174/391; 156/60

(57) ABSTRACT

Disclosed herein is a magnetic board including a composite film including a rigidity film and a ductility film, and a magnetic sheet attached to one surface of the composite film and having fracture lines formed on portions joined with the ductility film.

### CROSS REFERENCE TO RELATED APPLICATION

This application claims the benefit of Korean Patent Application No. 10-2012-0107136, filed on Sep. 26, 2012, entitled “Magnetic Board and Method for Manufacturing the Same”, which is hereby incorporated by reference in its entirety into this application.

### BACKGROUND OF THE INVENTION

1. Technical Field

The present invention relates to a magnetic board and a method for manufacturing the magnetic board.

2. Description of the Related Art

Generally, electromagnetic waves (or radiated noise) generated from electronic devices cause malfunction of electronic devices therearound, and when the electromagnetic waves are exposed to a human body, health of the human body is affected, or the like. Thus, in order to block electromagnetic waves generated from electronic devices, an electromagnetic wave interruptor made of a magnetic substance such as ferrite is installed in a corresponding electronic device and used. Such an electromagnetic wave interrupter is formed by attaching a protective sheet or an adhesive film to one surface or on both surfaces of a platy (i.e., plate-like) ferrite sintered body (U.S. Patent Laid Open Publication No. 20090117328). The platy ferrite sintered body is advantageous in that it has high magnetic permeability and excellent magnetic characteristics and can be fabricated to have a small thickness, but disadvantageous in that it is vulnerable to mechanical stress and impact. In particular, when a surface of an object to which the platy ferrite sintered body is to be attached is a curved surface or an uneven surface, it is difficult to tightly attach the platy ferrite sintered body, and even if the platy ferrite sintered body is attached, the platy ferrite sintered body may become split or damaged.

### SUMMARY OF THE INVENTION

The present invention has been made in an effort to provide a magnetic board and a method for manufacturing the magnetic board capable of reducing a process.

The present invention has also been made in an effort to provide a magnetic board and a method for manufacturing the magnetic board capable of reducing time and costs.

According to a preferred embodiment of the present invention, there is provided a magnetic board including: a composite film including a rigidity film and a ductility film; and a magnetic sheet attached to one surface of the composite film and having fracture lines formed on portions joined with the ductility film.

The composite film may be formed by attaching a plurality of rigidity films to one surface or on both surfaces of the ductility film.

The composite film may be formed by attaching a plurality of rigidity films in a grid pattern to one surface or both surfaces of the ductility film.

The fracture lines of the magnetic sheet may be formed to have a grid pattern.

The composite film may be attached to the other surface of the magnetic sheet.

The magnetic board may further include a protective film attached to the other surface of the magnetic sheet.

The rigidity film may be formed by including at least one of a soft magnetic polymer-based strengthening agent and a silicon (Si)-based strengthening agent.

The ductility film may be formed as a double-sided tape made of a PET material.

According to another preferred embodiment of the present invention, there is provided a method for manufacturing a magnetic board, including: preparing a magnetic sheet; attaching a composite film including a rigidity film and a ductility film to one surface of the magnetic sheet; and providing flexibility to the magnetic sheet with the composite film attached thereto.

In the providing of flexibility to the magnetic sheet, fracture lines may be formed on portions joined with the flexible film.

In the attaching of the composite film, the composite film may be formed by attaching a plurality of rigidity films to one surface or on both surfaces of the ductility film.

In the attaching of the composite film, the composite film may be formed by attaching a plurality of rigidity films in a grid pattern to one surface or both surfaces of the ductility film.

In the providing of flexibility to the magnetic sheet, fracture lines may be formed in a grid pattern on the magnetic sheet.

The method may further include: attaching the composite film to the other surface of the magnetic sheet, after the attaching of the composite film.

The method may further include: attaching a protective film to the other surface of the magnetic sheet, after the attaching of the composite film.

The rigidity film may be formed by including at least one of a soft magnetic polymer-based strengthening agent and a silicon (Si)-based strengthening agent.

The ductility film may be formed as a double-sided tape made of a PET material.

### BRIEF DESCRIPTION OF THE DRAWINGS

The above and other objects, features, and advantages of the present invention will be more clearly understood from the following detailed description taken in conjunction with the accompanying drawings, in which:

FIG. 1 is an exemplary view illustrating a magnetic board according to an embodiment of the present invention.

FIG. 2 is an exemplary view illustrating a composite film according to an embodiment of the present invention.

FIG. 3 is an exemplary view illustrating a magnetic board according to another embodiment of the present invention.

FIGS. 4 through 6 are exemplary views illustrating a method for manufacturing a magnetic board according to an embodiment of the present invention.

### DESCRIPTION OF THE PREFERRED EMBODIMENTS

The objects, features, and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side”, and the like, are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

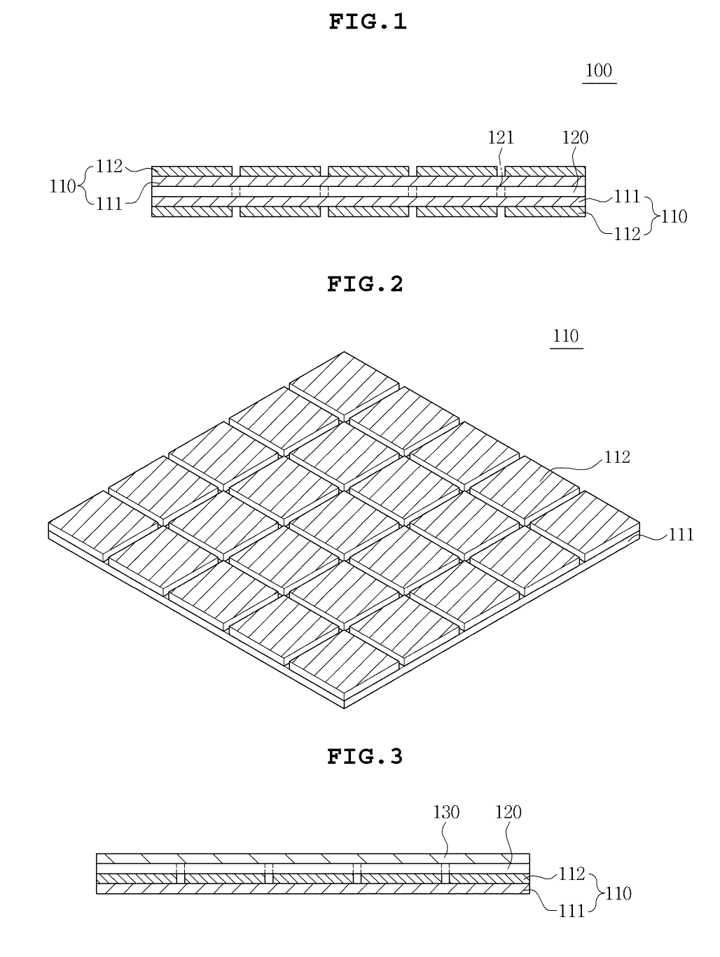

FIG. 1 is an exemplary view illustrating a magnetic board according to an embodiment of the present invention.

Referring to FIG. 1, a magnetic board 100 may include a composite film 110 and a magnetic sheet 120.

The composite film 110 may be attached to one surface or both surfaces of the magnetic sheet 120. The composite film 110 may be formed to fracture the magnetic sheet 120. According to an embodiment of the present invention, the composite film 110 may include a rigidity film 112 and a ductility film 111. For example, in the composite film 110, a plurality of rigidity films 112 may be formed on one surface of the ductility film 111. Here, the plurality of rigidity films 112 may be attached such that they are arranged on one surface or both surfaces of the ductility film 111. The rigidity films 112 may serve to protect the magnetic sheet 120 when flexibility is provided to the magnetic board 100 later. The ductility film 111 may serve to help the magnetic sheet 120 fracture when flexibility is provided to the magnetic board 100. Namely, when flexibility is provided to the magnetic board 100, a portion of the magnetic sheet 120 may be fractured by the composite film 110 while a portion thereof may be protected against fracturing. According to an embodiment of the present invention, a surface of the composite film 110 in contact with the magnetic sheet 120 may have adhesive strength. For example, at least one of the ductility film 111 and the rigidity film 112 of the composite film 110 may have adhesive strength. Thus, when the magnetic sheet 120 is fractured by the composite film 110, fragments cannot be released. In FIG. 1, the composite films 110 are formed on both surfaces of the magnetic sheet 120, but the present invention is not limited thereto. For example, the composite film 110 may be formed on only one surface of the magnetic sheet 120. Also, the composite film 110 may be formed on one surface of the magnetic sheet 120, while a protective film or an adhesive film known in the art may be formed on the other surface of the magnetic sheet 120.

The magnet sheet 120 may be a ferrite sheet. Alternatively, the magnetic sheet 120 may be a sheet in which ferrite and a dielectric substance are mixed. Since the magnetic sheet 120 has both permittivity and magnetic permeability, it can be fabricated to be thin (or fabricated to have a small thickness). One or more fracture lines 121 may be formed on the magnetic sheet 120. The fracture lines 121 are lines along which the magnetic sheet 120 is split. The fracture lines 121 may be formed on portions of the magnetic sheet 120 joined with the ductility film 111 of the composition film 110. Namely, the fracture lines 121 may be formed on a lower portion of the ductility film 111 in a thickness direction of the magnetic sheet 120. Due to the fracture lines 121 formed on the magnetic sheet 120, the magnetic board 100 may be provided with flexibility. Namely, the magnetic board 100 may be bent in various forms by virtue of the fracture lines 121 and the ductility film 111 of the composite film 110.

FIG. 2 is an exemplary view illustrating the composite film according to an embodiment of the present invention.

Referring to FIG. 2, the composite film 110 may include the rigidity film 112 and the ductility film 111. The ductility film 111 may be formed as a double-sided tape made of PET. However, the formation of the ductility film 111 as a double-sided tape made of PET is merely an embodiment and the present invention is not limited thereto. Namely, the ductility film 111 may be made of a material having adhesive strength and elongation and causing plastic deformation.

A plurality of rigidity films 112 may be formed in array on one surface of the ductility film 111. As illustrated in FIG. 2, the rigidity films 112 may be attached in a grid pattern (i.e., an area array type) to the ductility film 111. Also, the rigidity films 112 may be formed to include at least one of a soft magnetic polymer-based strengthening agent and a silicon (Si)-based strengthening agent. However, the shape and material of the rigidity films 112 are not limited thereto. Namely, the rigidity films 112 may be made of a material having rigidity capable of protecting the magnetic sheet 120 positioned below the rigidity film against force applied from the outside. The rigidity films 112 may be formed on the ductility film 111 through a screen printing method, a thin film deposition method such as PECVD, or the like, a patterning method using resist, or the like.

The magnetic sheet 120 at a portion on which the rigidity films 112 and the ductility film 111 are formed may be protected against eternal force by the rigidity films 112. However, the magnetic sheet 120 at a portion on which the rigidity film 112 is not formed and only the ductility film 111 is formed may be fractured by external force. For example, when the rigidity films 112 are formed in a grid pattern on the ductility film 111, the fracture lines of the magnetic sheet 120 may also be formed to have a grid pattern.

In this manner, since the magnetic sheet 120 corresponding to the portion where only the ductility film 111 is formed is fractured, flexibility may be provided to the magnetic board 100. Also, the configuration of providing flexibility to the magnetic board 100 may be easily modified by a skilled person in the art according to the form of the rigidity film 112 attached to an upper portion of the ductility film 111.

FIG. 3 is an exemplary view illustrating a magnetic board according to another embodiment of the present invention.

Referring to FIG. 3, the magnetic board 100 may include the composite film 110, the magnetic sheet 120, and a protective film.

The composite film 110 may be attached to one surface of the magnetic sheet 120. According to an embodiment of the present invention, the composite film 110 may include the rigidity film 112 and the ductility film 111. The composite film 110 may be configured by attaching a plurality of rigidity films 112 to one surface or both surfaces of the ductility film 111. Here, the plurality of rigidity films 112 may be attached in array to one surface or both surfaces of the ductility film 111. As illustrated in FIG. 3, the rigidity films 112 are formed on an upper portion of the ductility film 111 and bonded to the magnetic sheet 120. However, the position in which the rigidity films 112 are formed is not limited thereto. Namely, as for the positions in which the rigidity films 112 are formed, the rigidity films 112 may be selectively formed on at least one of upper and lower portions of the ductility film 111 by a skilled person in the art. The rigidity films 112 may serve to protect the magnetic sheet 120 when flexibility is provided to the magnetic board 100 later. The ductility film 111 may serve to help the magnetic sheet 120 fracture when flexibility is provided to the magnetic board 100. Namely, when flexibility is provided to the magnetic board 100, a portion of the magnetic sheet 120 may be fractured while a portion thereof may be protected against from fracturing by the composite film 110. According to an embodiment of the present invention, a surface of the composite film 110 in contact with the magnetic sheet 120 may have adhesive strength. For example, at least one of the ductility film 111 and the rigidity film 112 of the composite film 110 may have adhesive strength.

The magnetic sheet 120 may be a ferrite sheet. Alternatively, the magnetic sheet 120 may be a sheet in which ferrite and a dielectric substance are mixed. Since the magnetic sheet 120 has both permittivity and magnetic permeability, it can be fabricated to be thin (or fabricated to have a small thickness). One or more fracture lines 121 may be formed on the magnetic sheet 120. The fracture lines 121 are lines along which the magnetic sheet 120 is split. The fracture lines 121 may be formed on portions of the magnetic sheet 120 joined with the ductility film 111 of the composition film 110. Namely, the fracture lines 121 may be formed on a lower portion of the ductility film 111 in a thickness direction of the magnetic sheet 120. Due to the fracture lines 121 formed on the magnetic sheet 120, the magnetic board 100 may be provided with flexibility. Namely, the magnetic board 100 may be bent in various forms by virtue of the fracture lines 121 and the ductility film 111 of the composite film 110.

The protective film 130 may be formed on the other surface of the magnetic sheet 120. When the magnetic sheet 120 is fractured, the protective film 130 may prevent fractured fragments of the magnetic sheet 120 from being released to the outside. The protective film 130 may be a single-side or double-sided adhesive film. When the protective film 130 is a single-side adhesive film, an adhesive surface may be bonded to the magnetic sheet 120. When the protective film 130 is a double-sided adhesive film, one surface thereof may be bonded to the magnetic sheet 120 while the other surface thereof may be attached to a different element such as an antenna radiator, an electromagnetic circuit, or the like.

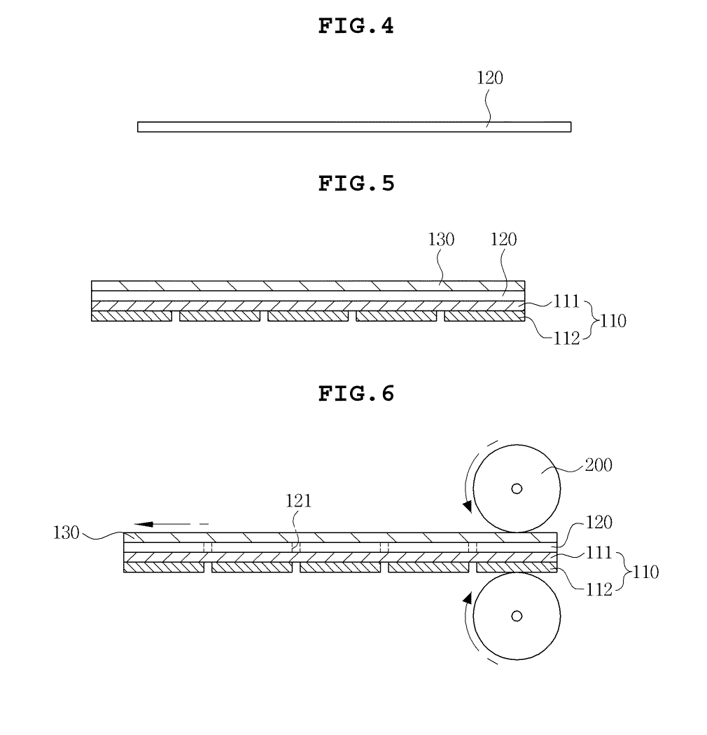

FIGS. 4 through 6 are exemplary views illustrating a method for manufacturing a magnetic board according to an embodiment of the present invention.

Referring to FIG. 4, the magnetic sheet 120 may be prepared. The magnetic sheet 120 may be a ferrite sheet. Alternatively, the magnetic sheet 120 may be a sheet in which ferrite and a dielectric substance are mixed. Since the magnetic sheet 120 has both permittivity and magnetic permeability, it can be fabricated to be thin

Referring to FIG. 5, the composite film 110 may be attached to one surface of the magnetic sheet 120. According to an embodiment of the present invention, the composite film 110 may include the rigidity film 112 and the ductility film 111. The composite film 110 may be configured by attaching a plurality of rigidity films 112 to one surface of the ductility film 111.

The ductility film 111 may serve to help the magnetic sheet 120 fracture when flexibility is provided to the magnetic sheet 100. The ductility film 111 may be made of a material having adhesive strength and elongation and causing plastic deformation. For example, the ductility film 111 may be formed as a double-sided tape made of PET. However, the formation of the ductility film 111 as a double-sided tape made of PET is merely an embodiment and the present invention is not limited thereto.

The rigidity film 112 may serve to protect the magnetic sheet 120 when flexibility is provided to the magnetic board 100 later. A plurality of rigidity may be formed in array on one surface of the ductility film 111. For example, the rigidity film 112 may be attached in a grid pattern (i.e., an area array type) to the ductility film 111. Also, the rigidity films 112 may be formed to include at least one of a soft magnetic polymer-based strengthening agent and a silicon (Si)-based strengthening agent. However, the shape and material of the rigidity films 112 are not limited thereto. The rigidity films 112 may be formed on the ductility film 111 through a screen printing method, a thin film deposition method such as PECVD, or the like, a patterning method using resist, or the like.

Also, the protective film 130 may be attached to the other surface of the magnetic sheet 120. The protective film 130 may prevent the fractured fragments of the magnetic sheet 120 from being released out.

In an embodiment of the present invention, the plurality of rigidity films 112 are formed on one surface of the ductility film 111, but it is merely illustrative and the present invention is not limited thereto. The plurality of rigidity films 112 may be formed on both surface of the ductility film 111, as well as on one surface thereof.

Also, in an embodiment of the present invention, the composite film 110 is attached to one surface of the magnetic sheet 120 and the protective film 130 is attached to the other surface of the magnetic sheet 120, but it is merely illustrative and the present invention is not limited thereto. Namely, the composite film 110, instead of the protective film 130, may be attached to the other surface of the magnetic sheet 120, as well as to one surface thereof

Referring to FIG. 6, flexibility may be provided to the magnetic sheet 120 with the composite film 110 and the protective film 130 attached thereto. The magnetic sheet 120 with the composite film 110 and the protective film 130 attached thereto may be inserted between rollers 200. As the magnetic sheet 120 is pressed by the rollers 200, it may be fractured. In this case, the magnetic sheet 120 positioned under the rigidity film 112 and the ductility film 111 may be protected by the rigidity film 112 against pressing force of the rollers 200. However, the magnetic sheet 120 positioned under the ductility film 111 of the composite film 110 may be affected by the pressing force of the roller 200 as it is. Namely, when the magnetic sheet 120 passes through between the rollers 200, the regions of the magnetic sheet 120 on which only the ductility film 111 is formed are fractured by the pressing force, forming the fracture lines 121. For example, when the rigidity films 112 are formed in a grid pattern on the ductility film 111, the fracture lines of the magnetic sheet 120 may also be formed in a grid pattern. In this manner, flexibility may be provided to the magnetic board 100 by the fracture lines of the magnetic sheet 120 formed by the composite film 110, and when the magnetic sheet 120 is fractured by the composite film 110, fractured fragments of the magnetic sheet 120 can be prevented from being released by the protective film 130.

In the embodiment of the present invention, the rollers 200 are used in providing flexibility to the magnetic board 100, but a method of providing flexibility to the magnetic board 100 is not limited thereto. Namely, flexibility may be provided to the magnetic board 100 by any methods of fracturing the magnetic sheet 120 as well as by the rollers 200.

According to the embodiments of the present invention, in the case of the magnetic board and the method for manufacturing the same, a half-cutting process as in the related art can be omitted by the composite film including the rigidity film and the ductility film.

Also, in the case of the magnetic board and the method for manufacturing the same according to the embodiments of the present invention, since the half-cutting process is omitted, time and costs can be reduced.

Although the embodiments of the present invention have been disclosed for illustrative purposes, it will be appreciated that the present invention is not limited thereto, and those skilled in the art will appreciate that various modifications, additions, and substitutions are possible, without departing from the scope and spirit of the invention.

Accordingly, any and all modifications, variations, or equivalent arrangements should be considered to be within the scope of the invention, and the detailed scope of the invention will be disclosed by the accompanying claims.

What is claimed is:

1. A magnetic board comprising:
a composite film including a rigidity film and a ductility film; and
a magnetic sheet attached to one surface of the composite film and having fracture lines formed on portions joined with the ductility film.

2. The magnetic board as set forth in claim 1, wherein the composite film is formed by attaching a plurality of rigidity films to one surface or on both surfaces of the ductility film.

3. The magnetic board as set forth in claim 1, wherein the composite film is formed by attaching a plurality of rigidity films in a grid pattern to one surface or both surfaces of the ductility film.

4. The magnetic board as set forth in claim 3, wherein the fracture lines of the magnetic sheet are formed to have a grid pattern.

5. The magnetic board as set forth in claim 1, wherein the composite film is attached to the other surface of the magnetic sheet.

6. The magnetic board as set forth in claim 1, wherein the magnetic board further includes a protective film attached to the other surface of the magnetic sheet.

7. The magnetic board as set forth in claim 1, wherein the rigidity film is formed by including at least one of a soft magnetic polymer-based strengthening agent and a silicon (Si)-based strengthening agent.

8. The magnetic board as set forth in claim 1, wherein the ductility film is formed as a double-sided tape made of a PET material.

9. A method for manufacturing a magnetic board, the method comprising:
preparing a magnetic sheet;
attaching a composite film including a rigidity film and a ductility film to one surface of the magnetic sheet; and
providing flexibility to the magnetic sheet with the composite film attached thereto.

10. The method as set forth in claim 9, wherein in the providing of flexibility to the magnetic sheet, fracture lines are formed on portions joined with the flexible film.

11. The method as set forth in claim 9, wherein in the attaching of the composite film, the composite film is formed by attaching a plurality of rigidity films to one surface or on both surfaces of the ductility film.

12. The method as set forth in claim 9, wherein in the attaching of the composite film, the composite film is formed by attaching a plurality of rigidity films in a grid pattern to one surface or both surfaces of the ductility film.

13. The method as set forth in claim 12, wherein in the providing of flexibility to the magnetic sheet, fracture lines are formed in a grid pattern on the magnetic sheet.

14. The method as set forth in claim 9, further comprising:
attaching the composite film to the other surface of the magnetic sheet, after the attaching of the composite film.

15. The method as set forth in claim 9, further comprising:
attaching a protective film to the other surface of the magnetic sheet, after the attaching of the composite film.

16. The method as set forth in claim 9, wherein the rigidity film is formed by including at least one of a soft magnetic polymer-based strengthening agent and a silicon (Si)-based strengthening agent.

17. The method as set forth in claim 9, wherein the ductility film is formed as a double-sided tape made of a PET material.
